(19) United States
(12) Patent Application Publication
(10) Pub. No.: US 2004/0119496 A1
(43) Pub. Date: Jun. 24, 2004

(54) Implementation of multiple flip flops as a standard cell using novel clock generation scheme

(75) Inventors: Heonchul Park, Cupertino, CA (US); Helena H. Nguyen, San Jose, CA (US); Trang Pham, Milpitas, CA (US)

Correspondence Address: BEVER HOFFMAN & HARMS, LLP, TRI-VALLEY OFFICE, 1432 CONCANNON BLVD., BLDG. G, LIVERMORE, CA, 94550, US

(73) Assignee: Infineon Technologies North America Corp.

(21) Appl. No.: 10/328,820

(22) Filed: Dec. 23, 2002

(51) Int. Cl. H03K 19/177

(52) U.S. Cl. 326/40

(57) ABSTRACT

Scan chain routing efficiency is improved in an integrated circuit (IC) such as an application specific integrated circuit (ASIC) by defining flip flop groupings prior to place and route. A flip flop grouping specifies the arrangement of multiple flip flops and the scan chain routing through those flip flops. The predetermined flip flop arrangement of the flip flop grouping then prevents undesirable flip flop placements during place and route. The flip flop grouping therefore minimizes the layout impacts of scan insertion while simplifying the place and route process. Different flip flop groupings can be used in a single IC design, and flip flop groupings can be combined with individual flip flops in the IC layout. A flip flop grouping can include control logic for the flip flops. Clock gating logic can be offloaded from the flip flops into the control logic to further improve layout efficiency.

### BACKGROUND OF THE INVENTION

1. Field of the Invention

The invention relates to programmable logic devices, and in particular a method and structure for increasing chip area efficiency and power savings in scan chain implementations.

2. Brief Description of Prior Art

Design for testability (DFT) is a key method for enhancing the testability of an IC, such as an application specific integrated circuit (ASIC). DFT typically involves replacing the flip flops in an ASIC with scan-testable flip flops, or “scan flops”. A scan flop is generally a flip flop having a multiplexed input, which allows the input of the flip flop to be switched between test data and actual data. The scan flops are daisy chained into a long shift register-like structure via their test inputs. This “scan chain” allows predetermined data strings to be shifted into the flip flops for testing purposes.

The scan chain is typically defined by synthesis tools during the pre-layout stage of the ASIC design process. Therefore, when the resulting netlist is converted into a physical layout during a subsequent place and route operation, sequentially connected scan flops in the scan chain may actually be placed far apart from one another in the physical layout.

For example, FIG. 1 shows a schematic diagram of a conventional ASIC 100 including scan flops 101, 102, 103, 104, 105, 106, 107, and 108, which are sequentially connected in a scan chain. Each of scan flops 101-108 includes clock input terminal CLK, a data input terminal D, a test enable terminal TE, a reset terminal R, a test input terminal TI, and an output terminal Q. Only the connections between the output terminal Q and test input terminal TI of consecutive scan flops in the scan chain are depicted for clarity. The scan chain formed by scan flops 101-108 allow test data Tin to be scanned into each of the flip flops, and allows test data Tout to be shifted out of each of the flip flops to test the functionality of ASIC 100.

The specific positions of scan flops 101-108 represent a place and route solution meeting the functional timing requirements of the ASIC. However, because the particular arrangement does not place the scan flops in their scan chain order, complex interconnect paths must be made to form the scan chain. Such convoluted interconnect layouts increase overall chip size and also can reduce chip speed. Also, the scan chain interconnects can interfere with, and therefore substantially complicate, the routing of other ASIC interconnects. In addition, since power-saving clock gating logic is incorporated into the ASIC design prior to place and route, the lengthy wires created by the scan chain can increase the effective load seen by the clock gating cells, thereby making it difficult to control clock insertion delay and skew.

Scan chains can be reordered during place and route to reduce layout inefficiency. Such reordering undesirably increases the complexity of the place and route operation, and also increases the time required for place and route. In addition, the reordering of scan chains typically requires that additional buffer cells be added to the design to maintain proper device timing and load handling. When clock gating logic is added, the place and route scripts become even more complex, and many iterations are required to control clock insertion delay and clock skew.

Accordingly, it is desirable to provide a structure and method for increasing scan chain efficiency while minimizing place and route complexity and improving control over clock skew.

### SUMMARY OF THE INVENTION

By grouping multiple flip flops into a predefined “flip flop grouping” that defines the physical arrangement of the flip flops and a scan chain path, the invention prevents the haphazard scan chain routing implemented by conventional IC design processes that merely define the scan chain path. Because the flip flop grouping specifies the physical arrangement of the flip flops (and any associated control logic), the elements of the flip flop grouping can be optimized for layout efficiency. Any number of flip flops can be incorporated into a flip flop grouping, and flip flop groupings can be combined with individual flip flops in an IC, based on design requirements and goals.

According to an embodiment of the invention, the flip flop grouping can be specified as a single-entity (standard) cell within a cell library, which not only simplifies place and route operations, and also allows an efficient scan chain to be incorporated into the prelayout netlist by synthesis tools.

According to an embodiment of the invention, a flip flop grouping can comprise standard scan flops with predefined scan chain interconnects. According to another embodiment of the invention, a flip flop grouping can include control logic to provide scan capability with or without clock gating. Such control logic can allow the flip flops in the flip flop grouping to be modified to minimize layout area consumption, improve performance, reduce setup time, and reduce power consumption. Furthermore, by incorporating the scan/clock gating logic for multiple flip flops into the control logic, layout area requirements for the flip flop grouping can be significantly reduced. According to an embodiment of the invention, clock skew for the flip flops in a flip flop grouping can be minimized by arranging the flip flops around the control logic so that the clock signal is evenly distributed to all the flip flops.

The present invention will be more fully understood in view of the following description and drawings.

### BRIEF DESCRIPTION OF THE DRAWINGS

FIG. 1 is a schematic diagram of an ASIC including a conventional scan chain layout.

FIG. 2 is a schematic diagram of an IC including a scan module in accordance with an embodiment of the invention.

FIG. 3 is a schematic diagram of a flip flop grouping, in accordance with an embodiment of the invention.

FIG. 4 is a schematic diagram of a control logic circuit for a flip flop grouping, in accordance with an embodiment of the invention.

FIG. 5 is a schematic diagram of a space-efficient flip flop for use in a flip flop grouping, in accordance with an embodiment of the invention.

### DETAILED DESCRIPTION

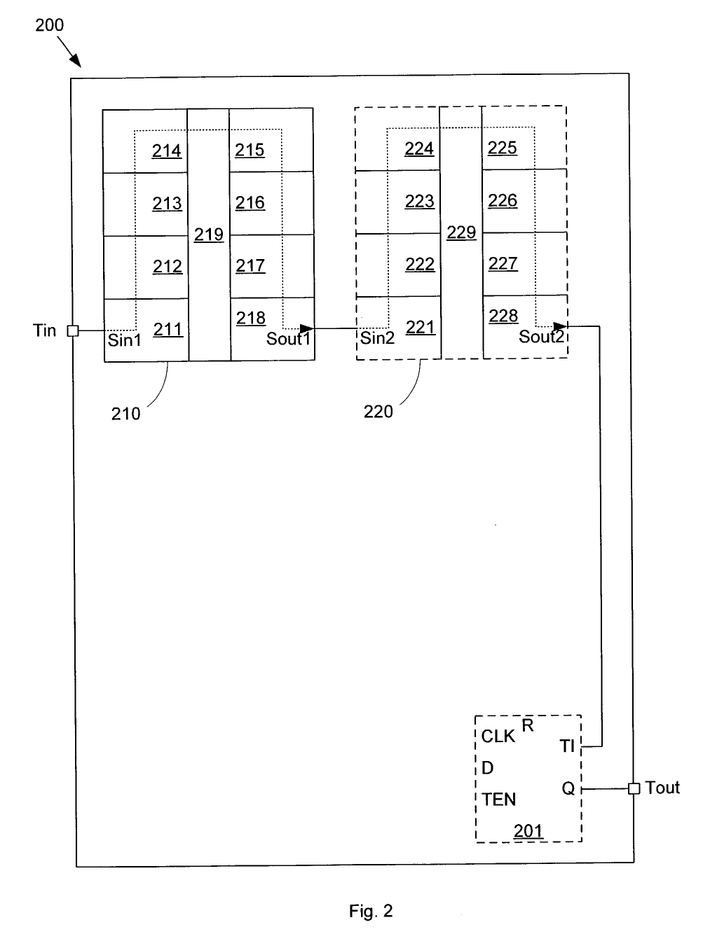

The invention provides enhanced IC layout efficiency by predefining a group of scan chained flip flops that are treated as a single unit during place and route, thereby minimizing the effects of scan chain routing inefficiency. FIG. 2 shows an IC 200 that includes a flip flop grouping 210 in accordance with an embodiment of the invention. Flip flop grouping 210 comprises a set of flip flops 211, 212, 213, 214, 215, 216, 217, and 218, and optional built-in control logic 219. Flip flops 211-218 are daisy chained (as indicated by the dotted arrow) between an input scan terminal Sin1 and an output scan terminal Sout1 in a scan chain configuration (i.e., the data output and the test input of successive flip flops are connected). This “partial scan chain” can then be incorporated into the full scan chain for IC 200. Note that while flip flop grouping 210 (and flip flop grouping 220, described below) is depicted as an 8-bit flip flop grouping (i.e., including eight flip flops) for explanatory purposes, the invention can be used with any grouping of two or more flip flops.

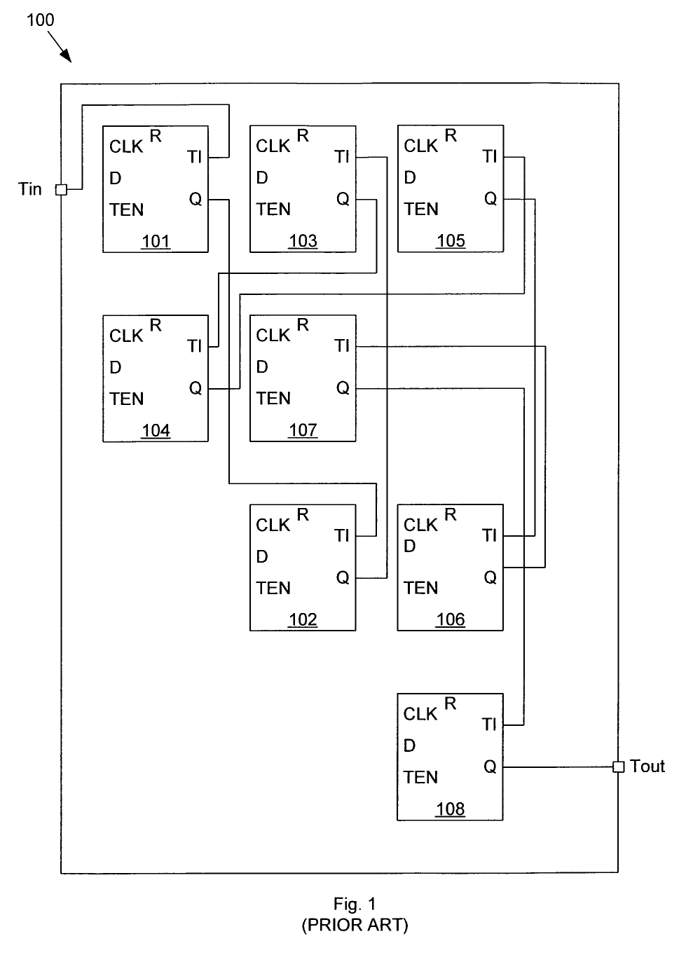

By specifying the physical arrangement of flip flops 211-218 in flip flop grouping 210, the scan chain routing between those flip flops (and any associated control logic) can be optimized and maintained throughout the IC design process. Since flip flop grouping 210 is treated a single entity (i.e., the predefined arrangement of flip flops 211-218 is maintained), the optimized scan chain routing is retained over the course of place and route and into the final IC layout. Flip flop grouping 210 can be part of a full scan chain with other flip flop groupings such as flip flop grouping 220, and/or other individual flip flops such as flip flop 201, thereby allowing test data Tin to be loaded into all the flip flops of IC 200 (and allowing test data Tout to be read out from those same flip flops). Flip flop grouping 220 can comprise another instance (or instances) of flip flop grouping 210, or can represent a different flip flop grouping (i.e., different arrangement, flip flop quantity, etc.). Individual flip flop 201 can comprise any type of flip flop that can be incorporated into a scan chain, including conventional scan flops such as scan flops 101-108, described with respect to FIG. 1. For clarity, only the scan chain connections are depicted in FIG. 2. Note that a full scan chain can include any number and order of flip flop groupings and individual flip flops, as indicated by the dashed lines around flip flop grouping 220 and individual flip flop 201. The specific combination and arrangement of flip flop groupings and individual flip flops will depend on the specific requirements of the ASIC design. Note further that flip flop groupings having different numbers of flip flops can be used in a single ASIC.

Flip flop grouping 220 includes flip flops 221, 222, 223, 224, 225, 226, 227, and 228, and optional built in control logic 229. Flip flops 221-228 are daisy chained between an input scan terminal Sin2 and an output scan terminal Sout2 to form a partial scan chain (indicated by the dotted arrow). By connecting scan output terminal Sout1 of flip flop grouping 210 with scan input terminal Sin2 of flip flop grouping 220, a scan chain formed from flip flops 211-218 and 221-228 can be formed. The only routing required to form this scan chain is the connection between scan output terminal Sout1 and scan input terminal Sin2. Accordingly, the resulting scan chain can be very space-efficient, using short wiring runs and minimal buffer insertions due to the layout optimization that can be implemented within flip flop groupings 210 and 220. In this manner, long, efficient scan chains can be easily implemented in an IC. Note that while flip flops 221-228 are shown surrounding control logic 229 for explanatory purposes, the flip flops and control logic in a flip flop grouping can have any specified arrangement.

According to various embodiments of the invention, flip flops 211-218 of flip flop grouping 210 can comprise standard scan flops or even non-scan flip flops that provide the desired scan capability via control logic 219. However, layout efficiency can often be improved even more by optimizing the flip flops for group arrangement and operation. A standard scan flop cell (i.e., a standard scan flop in a cell library) typically includes integrated scan logic. A flip flop grouping made up of such standard scan cells could provide efficient scan routing, but it could also consume more die area than necessary due to redundancies in the scan logic for each cell. Accordingly, by centralizing control in control logic 219, additional layout efficiency can be realized.

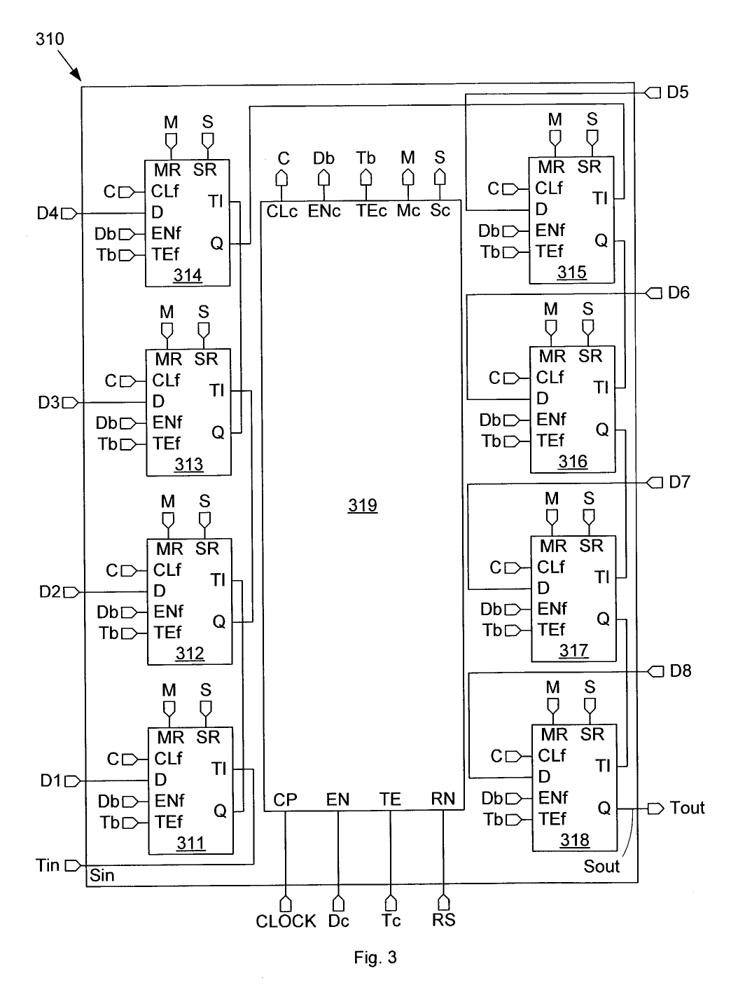

For example, FIG. 3 shows an 8-bit flip flop grouping 300 according to an embodiment of the invention. Flip flop grouping 310 can be defined in a cell library so that it can be readily incorporated into an IC design. Flip flop grouping 310 includes flip flops 311, 312, 313, 314, 315, 316, 317, and 318, and control logic 319. Each of flip flops 311-318 includes a clock terminal CLf, a data input terminal D, an input enable terminal ENf, a test enable terminal TEf, a master reset terminal MR, a slave reset terminal SR, a test input terminal TI, and an output terminal Q. The input terminal D of each of flip flops 311-318 is coupled to receive input data D1-D8, respectively. Note that according to other embodiments of the invention, flip flops 311-318 can include complementary inputs/outputs to improve switching speed and reduce the overall layout area of the flip flop. Note that by surrounding control logic 319 with flip flops 311-318, connections between control logic 319 and flip flops 311-318 can be efficiently made, although various other arrangements are possible.

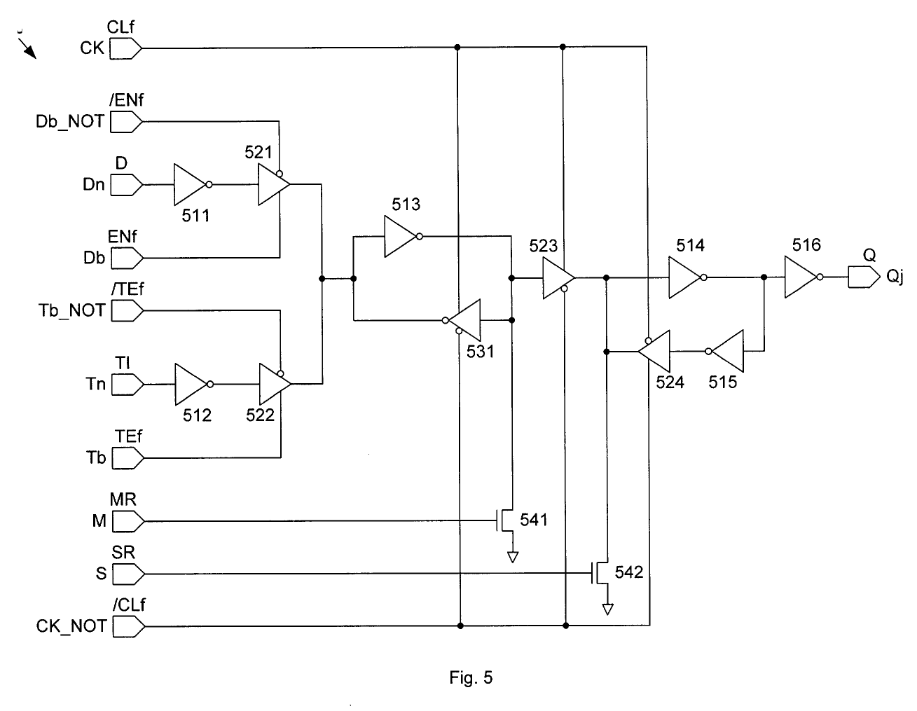

Each of flip flops 311-318 is a scan flop, and therefore data is loaded from either data input terminal D or test input terminal TI at each local clock pulse C at clock terminal CLf. During normal operation, a data enable signal Db is asserted at input enable terminal ENf, so that regular (i.e., non-test) data is loaded from data input terminal D. During testing operations, a test enable signal Tb is asserted at test enable terminal TEf, so that test data is loaded from test input terminal TI. Master reset terminal MR and slave reset terminal SR reset master and slave latches, respectively, within the flip flop (for example, as described in detail below with respect to FIG. 5) in response to master reset signal M and slave reset signal S, respectively.

Flip flops 311-318 are daisy chained to form a partial scan chain between a scan input terminal Sin and a scan output terminal Sout, with the output terminal Q being connected to the input terminal TI between successive flip flops. Test input terminal TI of flip flop 311 is connected to scan input terminal Sin, while output terminal Q of flip flop 318 is connected to scan output terminal Sout. Therefore, test data Tin can be scanned into the partial scan chain via scan input terminal Sin, while test data Tout can be read from scan output terminal Sout.

The behavior of flip flops 311-318 during both normal and test operations is controlled by control logic 319, which includes a clock input terminal CP, a data enable terminal EN, a test enable terminal TE, a reset terminal RN, a clock output terminal CLc, a data control terminal ENc, a test control terminal TEc, a master reset control terminal Mc, and a slave reset control terminal Sc. In response to a system clock signal CLOCK at a clock input terminal CP, control logic signal generates local clock signal C for each of flip flops 311-318. During normal operation, a data control signal Dc is asserted at data enable terminal EN, control logic 319 asserts data enable signal Db so that data at the data input terminal D of each flip flop is loaded on every local clock pulse C. On the other hand, during test mode a test control signal Tc is asserted at test enable terminal TE, control logic 319 asserts test enable signal Tb so that test data can be loaded into and/or read out of the partial scan chain formed by flip flops 311-318.

Control logic 319 can also provide consolidated clock gating control for flip flops 311-319 so that such circuitry can be eliminated from each flip flop. For example, control logic 319 can disable local clock signal C at clock output terminal CLc when both data control signal Dc and test control signal Tc are deasserted, thereby preventing activity and minimizing power consumption in flip flops 311-318. In this manner, a single clock gating circuit in control logic 319 can replace multiple clock gating circuits that would otherwise be added during the place and route step for each of flip flops 311-318.

Finally, the state of a reset signal RS at reset control terminal RN controls the states of master reset signal M and slave reset signal S. During non-reset operations, reset signal RS is deasserted, and control logic 319 deasserts master reset signal M and slave reset signal S. To perform a reset operation on the flip flops associated with control logic 319, reset signal RS is asserted at reset terminal RN, and in response, control logic 319 asserts master reset signal M and slave reset signal S at master reset control terminal Mc and slave reset control terminal Sc, respectively. Note that while the reset operation of flip flops are described herein using a reset signal that includes discrete master and slave reset signals, according to various other embodiments of the invention, the invention can be applied to flip flops that are reset by a single reset signal.

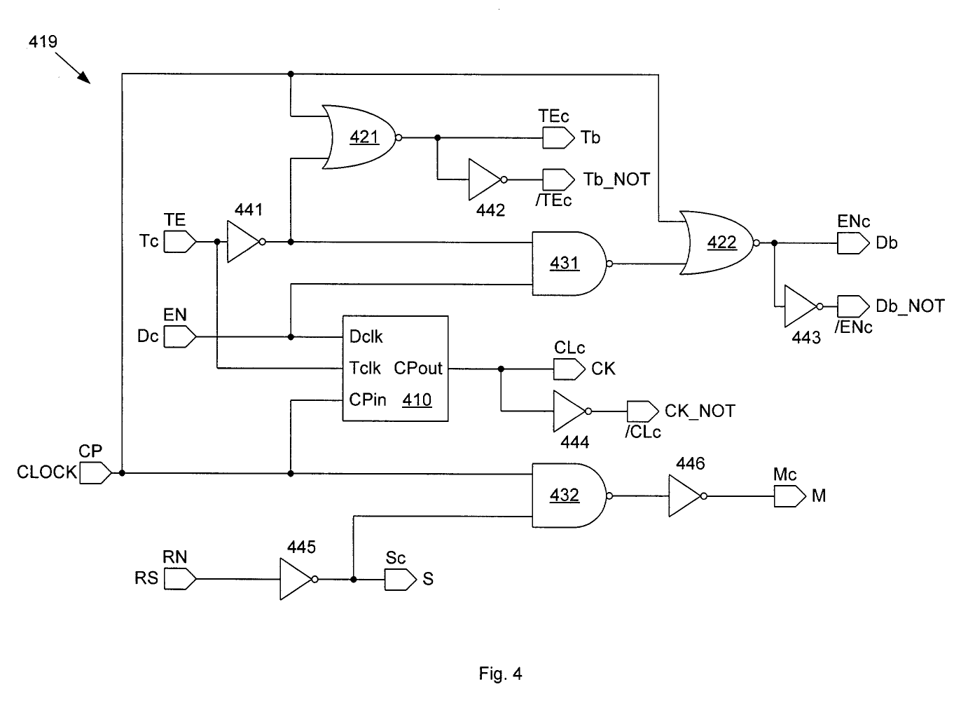

FIG. 4 shows a schematic diagram of a control logic circuit 419, which represents an implementation of control logic 319 (described with respect to FIG. 3), according to an embodiment of the invention. Control logic circuit 419 includes a clock input terminal CP, a data enable terminal EN, a test enable terminal TE, a reset terminal RN, a clock output terminal CLc, a data control terminal ENc, a test control terminal TEc, a master reset control terminal Mc, and a slave reset control terminal Sc, which correspond to the similarly labeled terminals of control logic 319 in FIG. 3. Control logic circuit further includes a complementary clock output terminal /CLc, a complementary data control terminal /ENc, a complementary test control terminal /TEc, a clock gating circuit 410, NOR gates 421 and 422, NAND gates 431 and 432, inverters 441, 442, 443, 444, and 445.

Clock gating for any flip flops associated with control logic circuit 419 is provided by clock gating circuit 410. Clock gating circuit 410 includes a data clock enable input Dclk that is connected to data enable terminal EN, a test clock enable input Tclk that is connected to test enable terminal TE, a clock pulse input CPin that is connected to clock input terminal CP, and a clock pulse output CPout that is connected to clock output terminal CLc. When data control signal Dc is asserted at data enable terminal EN or test control signal Tc is asserted at test enable terminal TE, clock gating circuit 410 uses a system clock signal CLOCK coupled to clock input terminal CP to provide a local clock signal CK to clock output terminal CLc. Note that while local clock signal CK will be described as tracking (i.e., directly following, with matching clock pulses) system clock signal CLOCK for explanatory purposes, according to other embodiments of the invention, local clock signal CK can follow system clock signal CLOCK but be inverted, or local clock signal CK can have a pattern that does not follow system clock signal CLOCK at all. Inverter 444 connected between clock pulse output CPout and complementary clock output terminal /CLc inverts local clock signal CK to provide a complementary local clock signal CK_NOT at complementary clock output terminal /CLc. When neither data control signal Dc nor test control signal Tc is asserted, clock gating circuit 410 holds clock pulse output CPout at a fixed level to halt the operation of any flip flops that are clocked by local clock signal CK and complementary local clock signal CK_NOT.

The states of data control signal Dc and test control signal Tc at data enable EN and test enable terminal TE, respectively, also determine the behavior of the flip flops associated with control logic circuit 419. Data enable terminal EN is connected to one input of NAND gate 431, while inverter 441 connects test input terminal TE and the other input of NAND gate 431. The output of NAND gate 431 is connected to one input of NOR gate 422, while clock input terminal CP is connected to the other input of NOR gate 422. The output of NOR gate 422 is connected to data control terminal ENc to provide data enable signal Db, while inverter 443 connects the output of NOR gate 422 with complementary data control terminal /ENc to provide complementary data enable signal Db_NOT.

When data control signal Dc is deasserted, the output of NAND gate 431 is logic HIGH, which forces the output of NOR gate 422 to a logic LOW state, regardless of the state of test control signal Tc and system clock signal CLOCK. However, when data control signal Dc is asserted while test control signal Tc is deasserted, the output of NAND gate 431 becomes a logic LOW output. The output of NOR gate 422 therefore is driven by the state of system clock signal CLOCK, so that data enable signal Db is simply the inverse of system clock signal CLOCK and complementary data enable signal Db tracks system clock signal CLOCK. The functional behavior of a flip flop having master and slave latches could then be controlled by this data enable signal Db (and local clock signal CK) as described below with respect to FIG. 5.

Meanwhile, the output of inverter 441 is also connected to an input of NOR gate 421. Clock input terminal CP is connected to the other input of NOR gate 421, and the output of inverter 441 is connected to test control terminal TEc to provide test enable signal Tb. Inverter 442 is connected between the output of NOR gate 421 and complementary test control terminal /TEc to provide complementary test enable signal Tb_NOT. Therefore, when test control signal Tc at test input terminal TE is deasserted, inverter 441 provides a logic HIGH signal to NOR gate 421, which forces test enable signal Tb to a logic LOW state (and complementary test enable signal Tb_NOT to a logic HIGH state), regardless of the state of system clock signal CLOCK. However, when test control signal Tc is asserted, inverter 441 provides a logic LOW signal to NOR gate 421, so that the output of NOR gate 421 is driven by the state of system clock signal CLOCK. Therefore, when test control signal Tc is asserted, test enable signal Tb is simply the inverse of system clock signal CLOCK, while complementary test enable signal Tb_NOT tracks system clock signal CLOCK. The functional behavior of a flip flop having master and slave latches could then be controlled by this test enable signal Tb (and local clock signal CK) as described below with respect to FIG. 5.

The state of reset signal RS at reset terminal RN controls the state of master reset signal M at master reset control terminal Mc and the state of slave reset signal S at slave reset control terminal Sc. Reset signal RS is an active LOW signal, and is maintained in a logic HIGH state during non-reset operations. Inverter 445 connects reset terminal RN with slave reset control terminal Sc, so that a logic HIGH signal at reset terminal RN holds slave reset signal S at slave reset control terminal Sc at a logic LOW level. Then, when reset signal RS is asserted (to a logic LOW state since reset signal RS is active LOW), slave reset signal S is asserted (to a logic HIGH state).

Meanwhile, the output of inverter 445 is also connected to an input of NAND gate 432, which has its output connected to master reset control terminal Mc by inverter 446. The other input of NAND gate 432 is coupled to receive system clock signal CLOCK. Therefore, while reset signal RS is deasserted (logic HIGH), the output of inverter 445 is at a logic LOW state, and the output of NAND gate 432 is maintained at a logic HIGH state, regardless of the state of system clock signal CLOCK. Inverter 446 then inverts the output of NAND gate 402, so that master reset signal M, is held at a logic LOW level while reset signal RS is deasserted. When reset signal RS is asserted (logic LOW), the output of inverter 445 is shifted to a logic HIGH, so that the output of NAND gate 432 is the inverse of system clock signal CLOCK, and master reset signal M therefore tracks system clock signal CLOCK. Note that while the operation of control logic circuit 419 is described with respect to an active LOW reset signal, according to other embodiments of the invention, reset signal RS could be an active HIGH signal.

FIG. 5 shows a space-saving and reduced setup time flip flop 500 for a predefined flip flop grouping in accordance with an embodiment of the invention. Flip flop 500 can be used for flip flops 311-318 described with respect to FIG. 3. Flip flop 500 includes a clock terminal CLf, a complementary clock terminal /CLf, a data input terminal D, a test input terminal TI, an input enable terminal ENf, a complementary input enable terminal /ENf, a test enable terminal TEf, a complementary test enable terminal /TEf, a master reset terminal MR, a slave reset terminal SR, inverters 511, 512, 513, 514, 515, and 516, a pass inverter 531, complementary metal-oxide-semiconductor (CMOS) pass gates 521, 522, 523, and 524, pass n-type metal-oxide-semiconductor (NMOS) pass transistors 541 and 542, and an output terminal Q. Clock terminal CLf, complementary clock terminal /CLf, data input terminal D, test input terminal TI, input enable terminal ENf, complementary input enable terminal /ENf, test enable terminal TEf, complementary test enable terminal /TEf, master reset terminal MR, and slave reset terminal SR are coupled to receive local clock signal CK, complementary local clock signal CK_NOT, regular (non-test) data Dn, test data Tn, data enable signal Db, complementary data enable signal Db_NOT, test enable signal Tb, complementary test enable signal Tb_NOT, master reset signal M, and slave reset signal S, respectively, which are described above with respect to FIG. 4.

Data input terminal D is connected to the input of inverter 511, while test input terminal TI is connected to the input of inverter 512. The output of inverter 511 is connected to the input of CMOS pass gate 521, which has its enable terminal connected to input enable terminal ENf and its complementary enable terminal connected to complementary input enable terminal /ENf. Therefore, while data enable signal Db is in a logic LOW state (and complementary data enable signal /Db is logic HIGH), CMOS pass gate 521 is turned off and does not pass the output of inverter 511. When data enable signal Db switches to logic HIGH (and complementary data enable signal Db_NOT goes logic LOW), CMOS pass gate 521 is turned on and pass the output of inverter 511. In a similar manner, the output of inverter 512 is connected to the input of CMOS pass gate 522, which has its enable terminal connected to test enable terminal TEf and its complementary enable terminal /TEf. When test enable signal Tb is in a logic LOW state (and complementary test enable signal Tb_NOT is logic HIGH), CMOS pass gate 522 is turned off and does not pass the output of inverter 512. When test enable signal Tb is switched to a logic HIGH state (and complementary test enable signal Tb_NOT goes to a logic LOW), CMOS pass gate 522 is turned on and pass the output of inverter 511. In this manner, data input via data input terminal D is enabled by asserting data enable signal Db, while test data input via test input terminal TI is enabled by asserting test enable signal Tb.

The input data is then passed to a master latch formed by inverters 513 and pass inverter 531. The outputs of CMOS pass gates 521 and 522 are connected to the input of inverter 513, which has its output connected to the input of pass inverter 531. The output of pass inverter 531 is connected to the input of inverter 513 to complete the master latch. The enable terminal of pass inverter 531 is connected to clock terminal CLf, while the complementary enable terminal of pass inverter 531 is connected to complementary clock terminal /CLf. Therefore, pass inverter 531 is enabled during the logic HIGH pulses of local clock signal CK. As described previously with respect to FIG. 4, data enable signal Db and test enable signal Tb also follow local clock signal CK, but are asserted on negative clock pulses, so during the negative (logic LOW) portions of local clock signal CK, data from either inverter 511 or 512 is passed by CMOS pass gate 521 or 522, respectively, to the input of inverter 513. Then, when local clock signal CK switches to a logic HIGH state, CMOS pass gates 521 and 522 are turned off, isolating inverter 513 from both inverters 511 and 512, while pass inverter 531 is turned on to latch the data into the master latch.

CMOS pass gate 523 connects the master latch formed by inverters 513 and 531 to a slave latch formed by inverters 514 and 515 and CMOS pass gate 524. The output of inverter 514 is connected to the input of inverter 515, which in turn has its output connected to the input of CMOS pass gate 524. The output of CMOS pass gate 524 is connected to the input of inverter 514 to complete the slave latch. CMOS pass gate 524 has its enable terminal connected to complementary clock terminal /CLf and its complementary enable terminal connected to clock terminal CLf. Meanwhile, the enable terminal of CMOS pass gate 523 is connected to clock terminal CLf, while the complementary enable terminal of CMOS pass gate 523 is connected to complementary clock terminal /CLf. Therefore, when local clock signal CK is in a logic HIGH state, CMOS pass gate 524 is off as CMOS pass gate 523 passes the data latched in the master latch to the input of inverter 514. Then, when local clock signal CK switches to a logic LOW state, CMOS pass gate 523 turns off, isolating the slave latch from the master latch, and CMOS pass gate 524 turns on, latching the data into the slave latch. The output of inverter 514 is connected to the input of inverter 516, which inverts the data stored in the slave latch and passes this data to output terminal Q, thereby providing the output data Qj from flip flop 500.

NMOS pass transistors 541 and 542 provide reset functionality to flip flop 500. NMOS pass transistor 541 is connected between the input of pass inverter 531 and ground, with its control terminal connected to master reset terminal MR, while NMOS pass transistor 542 is connected between the input of inverter 514 and ground, with its control terminal connected to slave reset terminal SR. Therefore, when master reset signal M is asserted at master reset terminal, NMOS pass transistor 541 is turned on, and the input of pass inverter 531 is pulled to ground, thereby forcing the master latch to store a logic LOW. As described previously with respect to FIG. 4, when master reset signal M is asserted, slave reset signal is concurrently asserted, so NMOS pass transistor 542 is also turned on. This pulls the input of inverter 514 to ground, thereby forcing the slave latch to store a logic HIGH. In this manner, flip flop 500 can be reset, such that output terminal Q will provide a logic LOW output immediately after the reset operation. Note that according to other embodiments of the invention, flip flop 500 can be set/reset to provide logic HIGH/LOW outputs immediately after the set/reset operations).

In this manner, the invention enables the implementation of layout-efficient scan chains that can minimize setup time while improving performance and reducing power consumption. The space-saving flip flop 500 shown in FIG. 5 and control logic circuit 419 shown in FIG. 4 allow a flip flop grouping such as flip flop grouping 310 shown in FIG. 3 to be implemented using only the metal-1 and metal-2 layers of an IC. This in turn can reduce congestion during place and route operations, as the metal-3 layer can be freely used during place and route to provide the most efficient interconnect routing. The various embodiments of the structures and methods of this invention that are described above are illustrative only of the principles of this invention and are not intended to limit the scope of the invention to the particular embodiments described. Thus, the invention is limited only by the following claims and their embodiments.

1. A method for creating an integrated circuit (IC), the method comprising:
defining a first flip flop grouping comprising a first plurality of flip flops in a first specified physical arrangement, each of the first plurality of flip flops having a data output terminal and a test input terminal, the first plurality of flip flops forming a daisy chain from a first flip flop to a second flip flop by connecting the data output terminal to the test input terminal of successive flip flops; and
placing a first instance of the first flip flop grouping in the IC.

2. The method of claim 1, further comprising adding the first flip flop grouping as a single entity cell to a cell library.

3. The method of claim 1, wherein the IC comprises an individual flip flop comprising a data output terminal and a test input terminal, the method further comprising connecting the data output terminal of the second flip flop of the first instance of the first flip flop grouping to the test input terminal of the individual flip flop.

4. The method of claim 1, wherein the IC comprises an individual flip flop comprising a data output terminal and a test input terminal, the method further comprising connecting the data output terminal of the individual flip flop to the test input terminal of the first flip flop of the first instance. of the first flip flop grouping.

5. The method of claim 1, further comprising:
placing a second instance of the first flip flop grouping in the IC; and
connecting the data output terminal of the second flip flop of the first instance to the test input terminal of the first flip flop of the second instance.

6. The method of claim 1, further comprising:
defining a second flip flop grouping comprising a second plurality of flip flops in a second specified physical arrangement, each of the second plurality of flip flops having a data output terminal and a test input terminal, the second plurality of flip flops forming a daisy chain between a third flip flop and a fourth flip flop by connecting the data output terminal to the test input terminal of successive flip flops;
placing a first instance of the second flip flop grouping in the IC as a single entity; and
connecting the data output terminal of the second flip flop of the first instance of the first flip flop grouping to the test input terminal of the third flip flop of the first instance of the second flip flop grouping.

7. The method of claim 6, wherein the second plurality is different from the first plurality.

8. The method of claim 1, wherein defining the first flip flop grouping comprises incorporating clock gating logic into the first flip flop grouping.

9. A single entity cell in a cell library, the single entity cell comprising:
a plurality of flip flops, each of the flip flops having a data output terminal and a test input terminal, the plurality of flip flops being arranged in a daisy chain from a first flip flop to a last flip flop by connecting the data output terminal and the test input terminal of successive flip flops;
a test input data terminal coupled to the test input terminal of the first flip flop; and
a test data output terminal coupled to the data output terminal of the last flip flop.

10. The single entity cell of claim 9, further comprising control logic for controlling the behavior of the plurality of flip flops.

11. The single entity cell of claim 10, wherein the plurality of flip flops is arranged to surround the control logic.

12. The single entity cell of claim 10, wherein the control logic includes clock gating logic for the plurality of flip flops.

13. The single entity cell of claim 12, wherein the control logic comprises a clock control circuit coupled to receive a data enable signal, a test enable signal, and a system clock signal, the clock control circuit generating a local clock signal only when the data enable signal or the test enable signal is asserted, the local clock signal being coupled to the plurality of flip flops.

14. The single entity cell of claim 13, wherein each of the plurality of flip flops includes a data input terminal, and wherein the control logic further comprises an operational control circuit coupled to receive the data enable signal, the test enable signal, and the system clock signal, wherein the operation control circuit generates a data control signal when the data enable signal is asserted, the data control signal instructing each of the plurality of flip flops to latch input data from the data input terminal in response to the local clock signal, and wherein the operation control circuit generates a test control signal when the test enable signal is asserted, the test control signal instructing each of the plurality of flip flops to latch test data from the test input terminal.

15. The single entity cell of claim 14, wherein the control logic further comprises a reset control circuit coupled to receive a reset signal, wherein the reset control circuit generates a reset control signal when the reset signal is asserted, the reset control signal causing each of the plurality of flip flops to be reset to a specified state.

16. The single entity cell of claim 15, wherein each of the plurality of flip flops further comprises:
a master latch; and
a slave latch, the reset control signal comprising a master reset signal and a slave reset signal, the master reset signal setting the master latch to a first state, and the slave reset signal setting the slave latch to a second state, the first state and the second state placing the flip flop in specified state.

17. The single entity cell of claim 16, wherein each of the plurality of flip flops further comprises:
a data input circuit including a first inverter connected between the data input terminal and a first complementary metal-oxide-semiconductor (CMOS) pass gate, the first CMOS pass gate being configured to turn on in response to the local clock signal when the data enable signal is asserted, the first CMOS pass gate having a first output terminal connected to the master latch; and
a test input circuit including a second inverter connected between the test input terminal and a second CMOS pass gate, the second CMOS pass gate being configured to turn on in response to the local clock signal when the test enable signal is asserted, the second CMOS pass gate having a second output terminal connected to the master latch.

18. An integrated circuit (IC) including a first flip flop grouping, the first flip flop grouping comprising:
a first plurality of flip flops, the first plurality of flip flops being daisy chained as a first portion of a scan chain, the first plurality of flip flops having a first predetermined arrangement relative to one another; and
a first control logic circuit comprising clock gating logic for each of the first plurality of flip flops, the first control logic circuit having a second predetermined arrangement relative to the first plurality of flip flops.

19. The IC of claim 18, further including a second flip flop grouping, the second flip flop grouping comprising:
a second plurality of flip flops, the second plurality being equal to the first plurality, the second plurality of flip flops being daisy chained as a second portion of the scan chain, the second plurality of flip flops having the first predetermined arrangement relative to one another; and
a second control logic circuit comprising clock gating logic for each of the second plurality of flip flops, the second control logic circuit having the second predetermined arrangement relative to the second plurality of flip flops.

20. The IC of claim 18, wherein the first control logic circuit includes a clock control circuit, the clock control circuit being coupled to receive an input enable signal, a test enable signal, and a system clock signal, the clock control circuit generating a local clock signal from the system clock signal when either the input enable signal or the test enable signal is asserted, the first plurality of flip flops being clocked by the local clock signal.

21. The IC of claim 20, wherein the first control logic circuit further comprises test control logic, the test control logic being coupled to receive the test enable signal and the system clock signal, the test control logic providing a test control signal to the first plurality of flip flops when the test enable signal is asserted, the test control signal instructing the first plurality of flip flops to load test data according to the local clock signal

22. The IC of claim 21, wherein the test control logic is further coupled to receive the input enable signal, the test control logic providing an input control signal to the first plurality of flip flops when the input enable signal is asserted and the test enable signal is deasserted, the input control signal instructing the first plurality of flip flops to load non-test data according to the local clock signal.

23. The IC of claim 22, wherein each of the first plurality of flip flops comprises:
a master latch;
a slave latch connected to the master latch in a flip flop configuration;
a data input circuit having a data input terminal, the data input circuit being configured to provide data at the data input terminal to the master latch in response to the input control signal; and
a test input circuit having a test input terminal, the test input circuit being configured to provide data at the test input terminal to the master latch in response to the test control signal.

24. The IC of claim 18, wherein the IC is an application specific integrated circuit (ASIC).
